(19) United States
(12) Patent Application Publication
(10) Pub. No.: US 2013/0105908 A1
(43) Pub. Date: May 2, 2013

(54) SEMICONDUCTOR DEVICE

(71) Applicant: Elpida Memory, Inc., Tokyo (JP)

(72) Inventor: Kanta SAINO, Tokyo (JP)

(73) Assignee: ELPIDA MEMORY, INC., Tokyo (JP)

(21) Appl. No.: 13/661,564

(22) Filed: Oct. 26, 2012

(30) Foreign Application Priority Data
Oct. 28, 2011 (JP) 2011-237030

(51) Int. Cl. H01L 27/092

(52) U.S. Cl. 257/369; 257/E27.067

(57) ABSTRACT

Provided is a semiconductor device that includes: a first electrode formed on a principal surface of a semiconductor substrate via a first insulating film; a second electrode formed on the principal surface of the semiconductor substrate via a second insulating film; a compensation film buried between the first electrode and the second electrode; and wiring formed on the first electrode and the second electrode from an upper surface of the first electrode through an upper surface of the compensation film to an upper surface of the second electrode to make contact with the upper surface of the first electrode and the upper surface of the second electrode.

### BACKGROUND OF THE INVENTION

1. Field of the Invention

The present invention relates to a semiconductor device.

2. Description of the Related Art

There is mounted on many semiconductor devices a CMIS (complementary metal insulator semiconductor) circuit that utilizes complementary operation characteristics of an n-channel MIS transistor (hereinafter, n-type transistor) and a p-channel MIS transistor (hereinafter, p-type transistor). In this CMIS circuit, the gate electrode of the n-type transistor and the gate electrode of the p-type transistor may be connected to each other by gate wiring (e.g., refer to JP5-121734A, JP8-125029A, and JP2006-245390A).

In the transistor used for the semiconductor device, required characteristics are different from one application to another, and a gate stack (gate insulating film and gate electrode) structure may be changed according to the characteristics. Characteristic adjustment based on the gate stack structure is used not only for a case where different characteristics are realized by the transistors that have similar polarities but also for a case where the symmetry of characteristics is improved between the n-type transistor and the p-type transistor.

In the recent semiconductor device, transistor miniaturization has been accompanied by an increase of leakage current from the gate insulating film. The increase of the gate leakage current hinders lower power consumption of the semiconductor device. As a method for preventing such leakage current, there is known a HKMG (high-k metal gate) stack structure that uses a high dielectric constant insulator for the gate insulating film and a metal material (metal gate) for the gate electrode.

Normally, in the MIS transistor, the threshold voltage of the transistor is adjusted based on the impurity density of a channel region. On the other hand, in the transistor employing the HKMG stack structure (hereinafter, HKMG transistor), not only the impurity density of the channel region but also the material or thickness of the gate insulating film and the material or thickness of the gate electrode are used as parameters for adjusting the threshold voltage. In other words, in the HKMG transistor, the HKMG stack structure of materials and thicknesses that differ according to required characteristics is employed. For example, JP2008-219006A or JP2011-003664A describes a method for forming a gate electrode by stacking a metal film and a silicon (polysilicon) film, and forming a gate electrode and a gate insulating film in individual manufacturing processes for transistors having different characteristics.

In the configuration where the gate stack structures are different and the gate electrodes are connected by the gate wiring as in the case of the HKMG transistor, it is important to connect the electrodes (gate electrodes of transistors) formed in the individual manufacturing processes to be separated without being electrically disconnected.

### SUMMARY OF THE INVENTION

In one embodiment, there is provided a semiconductor device that includes: a first electrode formed on the principal surface of a semiconductor substrate via a first insulating film;

a second electrode formed on the principal surface of the semiconductor substrate via a second insulating film;

a compensation film buried between the first electrode and the second electrode on the principal surface of the semiconductor substrate; and

a wiring formed from an upper surface of the first electrode through an upper surface of the compensation film to an upper surface of the second electrode to make contact with the upper surface of the first electrode and the upper surface of the second electrode. In this case, a height of the compensation film is not higher than one or more electrodes from among the first electrode and the second electrode.

In another embodiment, there is provided a semiconductor device that includes:

a first electrode formed on a principal surface of a semiconductor substrate via a first insulating film;

a second electrode formed on the principal surface of the semiconductor substrate via a second insulating film; a first wiring formed to cover an upper surface of the first electrode in contact with the first electrode;

a second wiring formed to cover an upper surface of the second electrode in contact with the second electrode; and

a compensation film buried between the side walls of the first electrode and the second electrode to connect the first electrode and the second electrode to each other. In this case, the compensation film covers none of the upper surfaces of the first electrode and the second electrode, and the first wiring and the second wiring are connected to each other on the compensation film located between the first electrode and the second electrode.

In another embodiment, there is provided a semiconductor device that includes:

in a first region of a principal surface of a semiconductor substrate,

a first electrode formed via a first insulating film; a second electrode formed via a second insulating film;

a compensation film buried between the first electrode and the second electrode; and a first wiring formed from an upper surface of the first electrode through an upper surface of the compensation film to an upper surface of the second electrode to make contact with the upper surface of the first electrode and the upper surface of the second electrode; and

in a second region of the principal surface of a semiconductor substrate,

a memory cell array including a plurality of memory cells for storing information; and

a second wiring for connecting the plurality of memory cells to each other. In this case, the first wiring and the second wiring are similar in configuration to each other.

In such a semiconductor device, a step between the upper surfaces of the first electrode and the second electrode and the principal surface of the semiconductor substrate exposed in a gap between the first electrode and the second electrode is reduced by the compensation film. Thus, coverage of the wiring for interconnecting the first electrode and the second electrode separated from each other is improved.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plan view illustrating an example of examining the structure of gate wiring for connecting gate electrodes to each other;

FIG. 1B is a sectional view illustrating the example of examining the structure of the gate wiring for connecting the gate electrodes to each other;

FIG. 2A is a plan view illustrating another example of examining the structure of the gate wiring for connecting the gate electrodes to each other;

FIG. 2B is a sectional view illustrating the another example of examining the structure of the gate wiring for connecting the gate electrodes to each other;

FIG. 3A is a plan view illustrating the problem of the gate wiring that directly makes contact with the gate electrodes to connect each other;

FIG. 3B is a sectional view illustrating the problem of the gate wiring that directly makes contact with the gate electrodes to connect each other;

FIG. 4A is a plan view illustrating a configuration example of a semiconductor device according to a first embodiment;

FIG. 4B is a sectional view cut along line A-A of the semiconductor device illustrated in FIG. 4A;

FIG. 4C a sectional view cut along line B-B of the semiconductor device illustrated in FIG. 4A;

FIG. 5A is a sectional view cut along line A-A of the semiconductor device illustrated in FIG. 4A, illustrating an example of a manufacturing procedure of the semiconductor device according to the first embodiment;

FIG. 5B is a sectional view cut along line B-B of the semiconductor device illustrated in FIG. 4A, illustrating an example of the manufacturing procedure of the semiconductor device according to the first embodiment;

FIG. 6A is a sectional view cut along line A-A of the semiconductor device illustrated in FIG. 4A, illustrating an example of the manufacturing procedure of the semiconductor device according to the first embodiment;

FIG. 6B is a sectional view cut along line B-B of the semiconductor device illustrated in FIG. 4A, illustrating an example of the manufacturing procedure of the semiconductor device according to the first embodiment;

FIG. 7A is a sectional view cut along line A-A of the semiconductor device illustrated in FIG. 4A, illustrating an example of the manufacturing procedure of the semiconductor device according to the first embodiment;

FIG. 7B is a sectional view cut along line B-B of the semiconductor device illustrated in FIG. 4A, illustrating an example of the manufacturing procedure of the semiconductor device according to the first embodiment;

FIG. 8A is a sectional view cut along line A-A of the semiconductor device illustrated in FIG. 4A, illustrating an example of the manufacturing procedure of the semiconductor device according to the first embodiment;

FIG. 8B is a sectional view cut along line B-B of the semiconductor device illustrated in FIG. 4A, illustrating an example of the manufacturing procedure of the semiconductor device according to the first embodiment;

FIG. 9A is a sectional view cut along line A-A of the semiconductor device illustrated in FIG. 4A, illustrating an example of the manufacturing procedure of the semiconductor device according to the first embodiment;

FIG. 9B is a sectional view cut along line B-B of the semiconductor device illustrated in FIG. 4A, illustrating an example of the manufacturing procedure of the semiconductor device according to the first embodiment;

FIG. 10A is a sectional view cut along line A-A of the semiconductor device illustrated in FIG. 4A, illustrating an example of the manufacturing procedure of the semiconductor device according to the first embodiment;

FIG. 10B is a sectional view cut along line B-B of the semiconductor device illustrated in FIG. 4A, illustrating an example of the manufacturing procedure of the semiconductor device according to the first embodiment;

FIG. 11A is a sectional view cut along line A-A of the semiconductor device illustrated in FIG. 4A, illustrating an example of the manufacturing procedure of the semiconductor device according to the first embodiment;

FIG. 11B is a sectional view cut along line B-B of the semiconductor device illustrated in FIG. 4A, illustrating an example of the manufacturing procedure of the semiconductor device according to the first embodiment;

FIG. 12A is a plan view of a memory cell array region, illustrating a configuration example of the semiconductor device according to a second embodiment;

FIG. 12B is a plan view of a peripheral circuit region, illustrating a configuration example of the semiconductor device according to the second embodiment;

FIG. 13A is a sectional view cut along line X-X of the memory cell array region illustrated in FIG. 12A;

FIG. 13B is a sectional view cut along line Y-Y of the peripheral circuit region illustrated in FIG. 12B;

FIG. 14A is a sectional view cut along line X-X of the memory cell array region illustrated in FIG. 12A, illustrating an example of the manufacturing procedure of the semiconductor device according to the second embodiment;

FIG. 14B is a sectional view cut along line Y-Y of the peripheral circuit region illustrated in FIG. 12B, illustrating an example of the manufacturing procedure of the semiconductor device according to the second embodiment;

FIG. 15A is a sectional view cut along line X-X of the memory cell array region illustrated in FIG. 12A, illustrating an example of the manufacturing procedure of the semiconductor device according to the second embodiment;

FIG. 15B is a sectional view cut along line Y-Y of the peripheral circuit region illustrated in FIG. 12B, illustrating an example of the manufacturing procedure of the semiconductor device according to the second embodiment;

FIG. 16A is a sectional view cut along line X-X of the memory cell array region illustrated in FIG. 12A, illustrating an example of the manufacturing procedure of the semiconductor device according to the second embodiment;

FIG. 16B is a sectional view cut along line Y-Y of the peripheral circuit region illustrated in FIG. 12B, illustrating an example of the manufacturing procedure of the semiconductor device according to the second embodiment;

FIG. 17A is a sectional view cut along line X-X of the memory cell array region illustrated in FIG. 12A, illustrating an example of the manufacturing procedure of the semiconductor device according to the second embodiment;

FIG. 17B is a sectional view cut along line Y-Y of the peripheral circuit region illustrated in FIG. 12B, illustrating an example of the manufacturing procedure of the semiconductor device according to the second embodiment;

FIG. 18A is a sectional view cut along line X-X of the memory cell array region illustrated in FIG. 12A, illustrating an example of the manufacturing procedure of the semiconductor device according to the second embodiment; and

FIG. 18B is a sectional view cut along line Y-Y of the peripheral circuit region illustrated in FIG. 12B, illustrating an example of the manufacturing procedure of the semiconductor device according to the second embodiment;

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

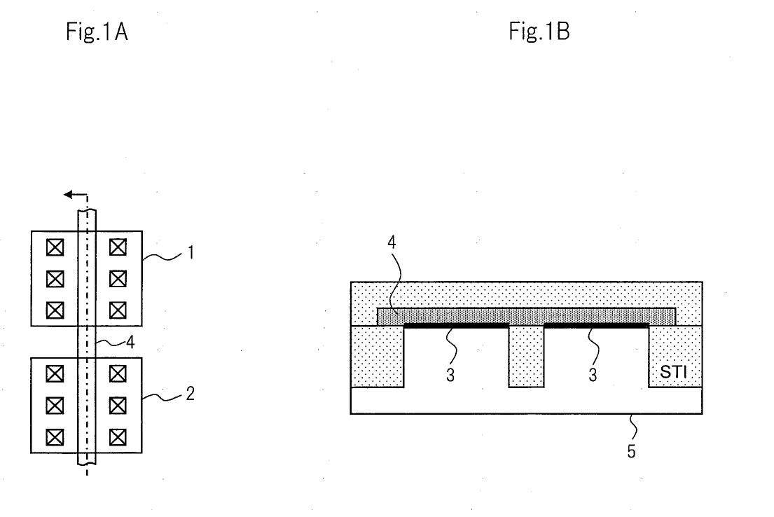

A transistor is constructed such that element forming regions are separated to serve as source, drain and channel regions by STI (shallow trench isolation) which is buried by, for example, an insulator in a trench, and a gate insulating film and a gate electrode are formed in each channel region. Generally, when the gate electrodes of the transistors are connected by gate wiring as illustrated in FIGS. 1A and 1B, gate wiring 4 is disposed to be used for the gate electrodes of first transistor 1 and second transistor 2 on semiconductor substrate 5 including a gate insulating film and STI (hereinafter, isolation layer). FIGS. 1A and 1B illustrate a configuration example where materials and thicknesses of gate insulating films 3 and gate electrodes of first transistor 1 and second transistor 2 are similar.

The inventors have examined a method for connecting the gate electrodes of the transistors by gate wiring different from each other in gate stack structure as in the case of aforementioned HKMG transistor and formed in individual manufacturing processes to be separately arranged near to each other.

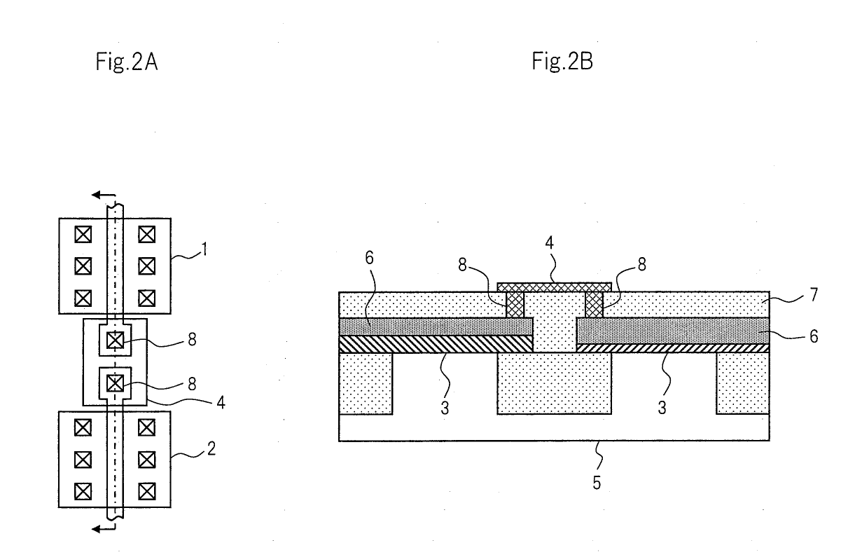

For example, FIGS. 2A and 2B illustrates such a method, which forms insulating layer 7 on semiconductor substrate 5 to cover gate electrodes 6 of first transistor 1 and second transistor 2, forms gate wiring 4 on insulating layer 7, buries conductors (contacts 8) in openings formed in insulating layer 7, connects gate electrodes 6 with gate wiring 4 on insulating layer 7 via contacts 8.

However, in the structure illustrated in FIGS. 2A and 2B, there is a problem, namely, the limit imposed on the distance that is arranged between first transistor 1 and second transistor 2 by the processing method of contacts 8. In other words, since the two transistors adjacent to each other must be separated from each other by a distance that allows sufficient area to form at least two contacts 8 in series, the integration density of the transistors is reduced.

The inventors have examined a structure where gate wiring 4 is formed to directly make contact with the upper surfaces of the gate electrodes of first transistor 1 and second transistor 2. This structure ensures that electric connection of gate electrodes 6 of the transistors formed in the individual manufacturing processes will be separately arranged without using insulating layer 7 or contact 8.

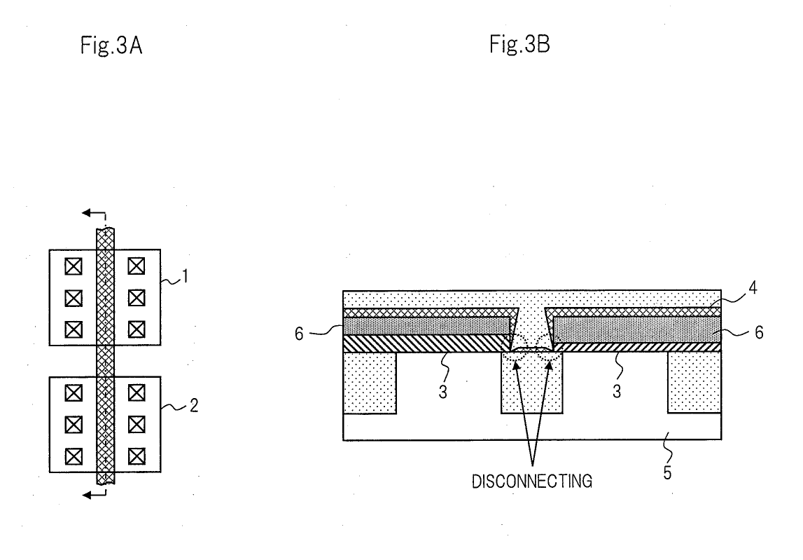

However, as illustrated in FIGS. 3A and 3B, when the upper surfaces of separately arranged gate electrodes 6 are connected to each other, the step between the upper surface of gate electrode 6 and the principal surface of semiconductor substrate 5 between gate electrodes 6 may cause disconnection of gate wiring 4. In particular, when gate insulating film 3 and gate electrode 6 are thicker (step is larger) and an interval between the gate stacks is narrower, there is a higher possibility that gate wiring 4 as a conductor film may not be uniformly formed on the side wall of the step part or the principal surface of semiconductor substrate 5 to be disconnected (wiring coverage is reduced).

The present invention provides a configuration for preventing such disconnection of gate wiring 4, and its manufacturing method.

### First Embodiment

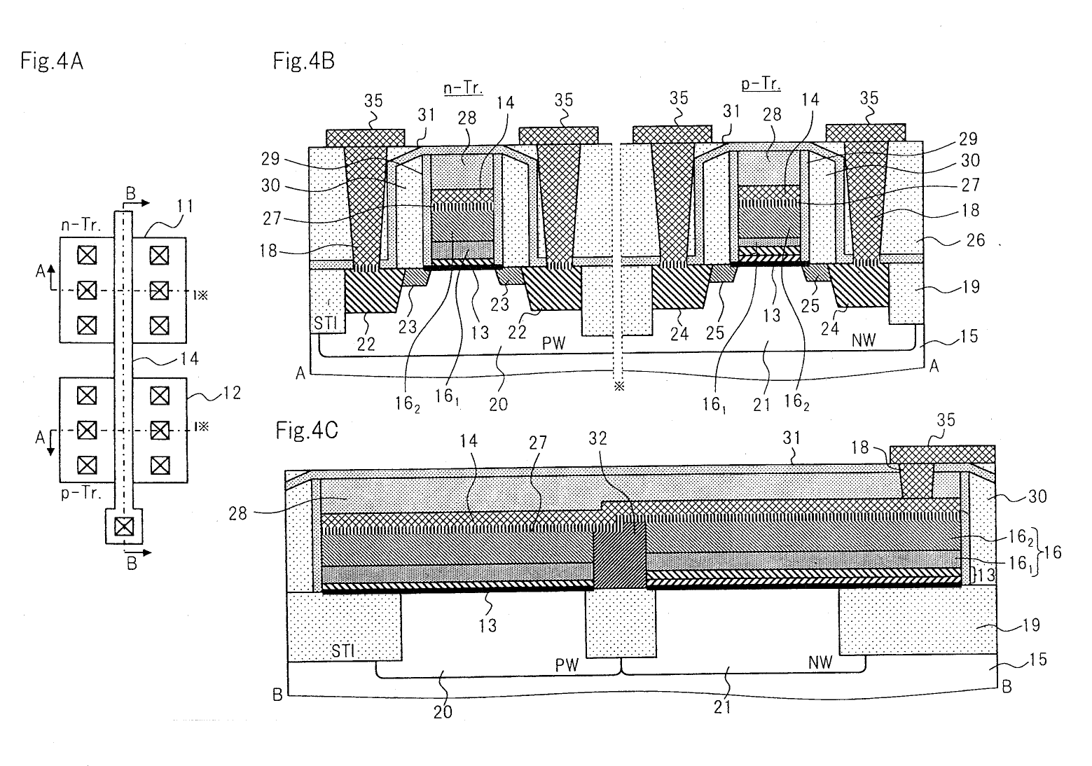

FIG. 4A is a plan view illustrating a configuration example of a semiconductor device according to a first embodiment, FIG. 4B is a sectional view cut along line A-A of the semiconductor device illustrated in FIG. 4A, and FIG. 4C is a sectional view cut along line B-B of the semiconductor device illustrated in FIG. 4A.

As illustrated in FIGS. 4A to 4C, the semiconductor device according to the first embodiment includes n-type transistor (n-Tr) 11 and p-type transistor (p-Tr) 12, and gate electrodes 16 of n-type transistor 11 and p-type transistor 12 are connected to each other by gate wiring 14. The present invention can be applied not only to the combination of n-type transistor 11 and p-type transistor 12 but also may be applied to the combination of n-type transistor 11 and n-type transistor 11 and the combination of p-type transistor 12 and p-type transistor 12. In the present invention, the number of transistors connected to gate wiring 14 is not limited to two. The number of transistors can be three or more.

Semiconductor substrate 15 is separated, by isolation layer (STI) 19, into P well region (PW) 20 that is an element forming region of n-type transistor 11 and N well region (NW) 21 that is element forming region of p-type transistor 12. In the element forming region of n-type transistor 11, for example, high density n-type impurity diffusion layer 22 that is a drain-source is formed, and low density p-type impurity diffusion layer 23 is formed inside high density n-type impurity diffusion layer 22. In the element forming region of p-type transistor 12, for example, high density p-type impurity diffusion layer 24 that is a drain-source is formed, and low density n-type impurity diffusion layer 25 is formed inside high density p-type impurity diffusion layer 24. A source or a drain including high density n-type impurity diffusion layer 22 or high density p-type impurity diffusion layer 24 and external wiring 35 are connected to each other via contact 18 formed in interlayer insulating layer 26 on the semiconductor substrate.

Between the source and the drain of each of n-type transistor 11 and p-type transistor 12, gate insulating film 13 including a high dielectric constant (high-k) insulating film is formed, and gate electrode 16 made of a laminate film including metal film 16₁ and Si film 16₂ is formed thereon. Gate wiring 14 is further formed thereon via metal silicide film 27. The high-k insulating film is made of an insulator (e.g., HfO₂ or Al₂O₃) higher in dielectric constant than silicon dioxide (SiO₂) conventionally used for the gate insulating film of the transistor.

Cap layer 28 including an insulator is deposited on gate wiring 14. The side faces of gate electrode 16 and gate wiring 14 including cap layer 28 are covered with offset spacer 29 and side wall spacer 30 including insulators, and the entire gate stack including offset spacer 29 and side wall spacer 30 is covered with liner film 31 including an insulator.

N-type transistor 11 and p-type transistor 12 are not limited to the configuration illustrated in FIGS. 4A to 4C. Any configuration can be employed for transistors to which the present invention is applied as long as the gate stack structures are different.

In this configuration, the semiconductor device according to this embodiment is configured, as illustrated in FIG. 4C, such that gate compensation film 32 is buried between separately arranged n-type transistor 11 and p-type transistor 12 on the principal surface of semiconductor substrate 15.

Gate wiring 14 is formed from the upper surface of gate electrode 16 of n-type transistor 11 through the upper surface of gate compensation film 32 to the upper surface of gate electrode 16 of p-type transistor 12.

Alternatively, the semiconductor device according to this embodiment is configured such that gate compensation film 32 is buried between the side walls of gate electrode 16 of n-type transistor 11 and gate electrode 16 of p-type transistor 12 to connect gate electrode 16 of n-type transistor 11 and gate electrode 16 of p-type transistor 12 to each other. Gate compensation film 32 does not cover any of the upper surfaces of gate electrode 16 of n-type transistor 11 and gate electrode 16 of p-type transistor 12. Gate electrode 16 of n-type transistor 11 and gate electrode 16 of p-type transistor 12 are connected to each other on gate compensation film 32 by gate wiring 14.

Gate compensation film 32 only needs to be formed, for example with a thickness that enables gate electrode 16 from among at least one or more n-type transistors 11 and p-type transistors 12, that are adjacent to each other, to match the upper surface.

Alternatively, n-type transistor 11 and p-type transistor 12 adjacent to each other are formed so that the height of gate electrode 16 of at least one transistor is not higher than that of gate compensation film 32.

In this configuration, the step between the upper surfaces of gate electrodes 16 of n-type transistor 11 and p-type transistor 12 formed in the individual manufacturing processes to be separately arranged and the principal surface of semiconductor substrate 15 exposed between gate electrodes 16 is reduced by gate compensation film 32. Thus, wiring coverage of the gate wiring for interconnecting gate electrodes 16 is improved, and disconnection of gate wiring 14 is prevented.

Gate compensation film 32 only needs to be able to reduce the step between the upper surface of gate electrode 16 and the principal surface of semiconductor substrate 15. In the present invention, there is no limitation on the material that can be used for gate compensation film 32. For gate compensation film 32, a metal or a conductor such as a conductive semiconductor can be used, or an insulator can be used. In this embodiment, as gate compensation film 32, for example, a silicon containing lo film (polycrystal silicon film or the like doped with impurities) is used. In the semiconductor device according to this embodiment, a plurality of laminate films (gate electrodes 16) adjacent to each other are electrically connected by wiring (gate wiring 14). Thus, the use of a conductor for gate compensation film 32 reinforces the electric connection of the laminate films. It is accordingly desirable to use the conductor for gate compensation film 32. Further, since the silicon containing film has high processability, it is more desirable to use a silicon containing film such as a polycrystal silicon film for gate compensation film 32.

In the example illustrated in FIGS. 4A to 4C, gate compensation film 32 is formed so that its upper surface can match the upper surfaces of gate electrodes 16 of the transistors that are different from each other in height. As illustrated in FIGS. 4A to 4C, gate insulating film 13 of the p-type transistor is formed thicker than that of the n-type transistor. Thus, a step corresponding to the film thickness difference of gate insulating film 13 is generated on the upper surface of gate compensation film 32. However, since the step corresponding to the film thickness difference is sufficiently lower than that corresponding to the thicknesses of gate insulating film 13 and gate electrode 16, and the step part is not held between gate electrodes 16, reduction of the wiring coverage of gate wiring 14 is limited.

As described above, in the example illustrated in FIGS. 4A to 4C, gate compensation film 32 is formed so that its upper surface can match the upper surfaces of gate electrodes 16 of the transistors that are different from each other in height. However, it is not always necessary to match the upper surface of gate compensation film 32 with the upper surface of gate electrode 16 of adjacent n-type transistor 11 or p-type transistor 12. Gate wiring 14 can be formed lower or higher than the upper surface of gate electrode 16 within a range where the wiring coverage is not reduced.

In the semiconductor device including the HKMG transistor, when gate wiring 14 is thinner or gate electrode 16 is higher (gate stack is thicker) following the miniaturization of the transistor, the gap between gate electrodes 6 is reduced, thus creating a possibility in which the wiring coverage of the conductor film (gate wiring 14) formed between the gate stacks will be reduced. This embodiment can be effectively applied to a semiconductor device including such a transistor.

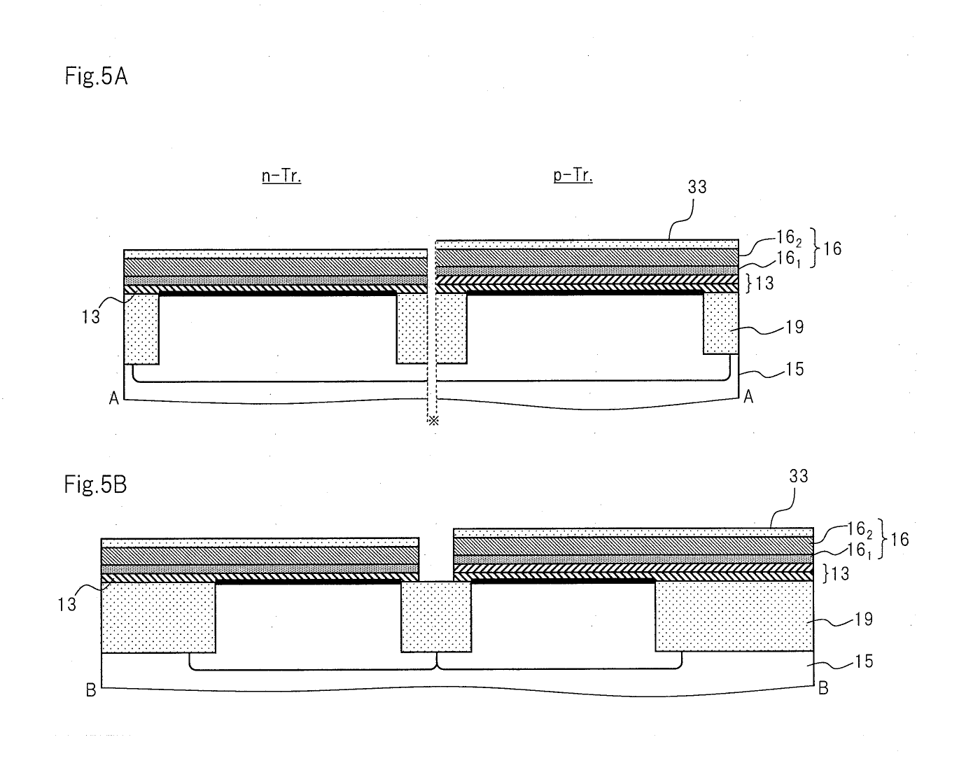

Next, referring to FIGS. 5A to 11B, a method for manufacturing the semiconductor device according to this embodiment will be described.

FIGS. 5A to 11B are sectional views illustrating an example of a manufacturing procedure of the semiconductor device according to the first embodiment: each A in FIGS. 5A to 11B is a sectional view cut along line A-A of the semiconductor device illustrated in FIG. 4A, and each B in FIGS. 5A to 11B is a sectional view cut along line B-B of the semiconductor device illustrated in FIG. 4A. However, each of FIGS. 5A to 11B illustrates the relationship between layers in the manufacturing process, and thus the plan views of FIGS. 4A and 4B do not correspond to all the sectional views of FIGS. 5A to 11B.

As illustrated in FIGS. 5A and 5B, first, gate insulating films 13 made of high dielectric constant materials (e.g., HfO₂) are formed in the element forming regions of n-type transistor 11 and p-type transistor 12 on semiconductor substrate 15 by, for example, ALD (atomic layer deposition). The element forming region of each transistor can be formed by forming the STI, by a known method, and introducing an impurity semiconductor for each region separated by the STI. FIGS. 5A and 5B illustrate a configuration example where as gate insulating film 13 of p-type transistor 12, a film made of a high dielectric constant material (e.g., Al₂O₃) is further stacked on the HfO₂ film by using the ALD or the like. Any method can be used for changing the thickness of gate insulating film 13 at n-type transistor 11 or of p-type transistor 12. FIGS. 5A and 5B illustrate the example where the materials or the film thicknesses of gate insulating film 13 are different between n-type transistor 11 and p-type transistor 12. However, the materials or the film thicknesses of gate electrodes 16 can be different.

Then, metal film (metal gate) 16₁ made of TiN or the like is formed on each gate insulating film 13 by using, for example, PVD (physical vapor deposition), and Si film (a-Si gate) 16₂ made of amorphous silicon or the like is stacked thereon by using, for example, CVD (chemical vapor deposition) to form gate electrode 16. FIGS. 5A and 5B illustrate the example where protective layer 33 made of, for example, SiO₂, is formed on Si film 16₂.

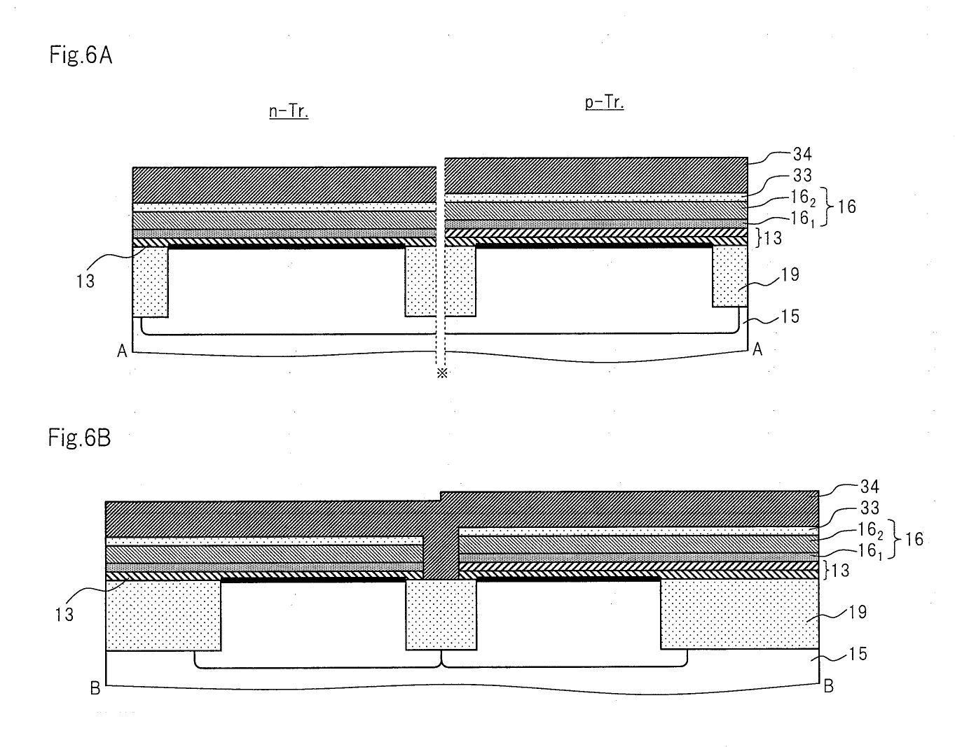

Then, as illustrated in FIGS. 6A and 6B, polycrystal silicon (poly-Si) layer 34 is formed to cover the entire surface of semiconductor substrate 15 including gate electrode 16.

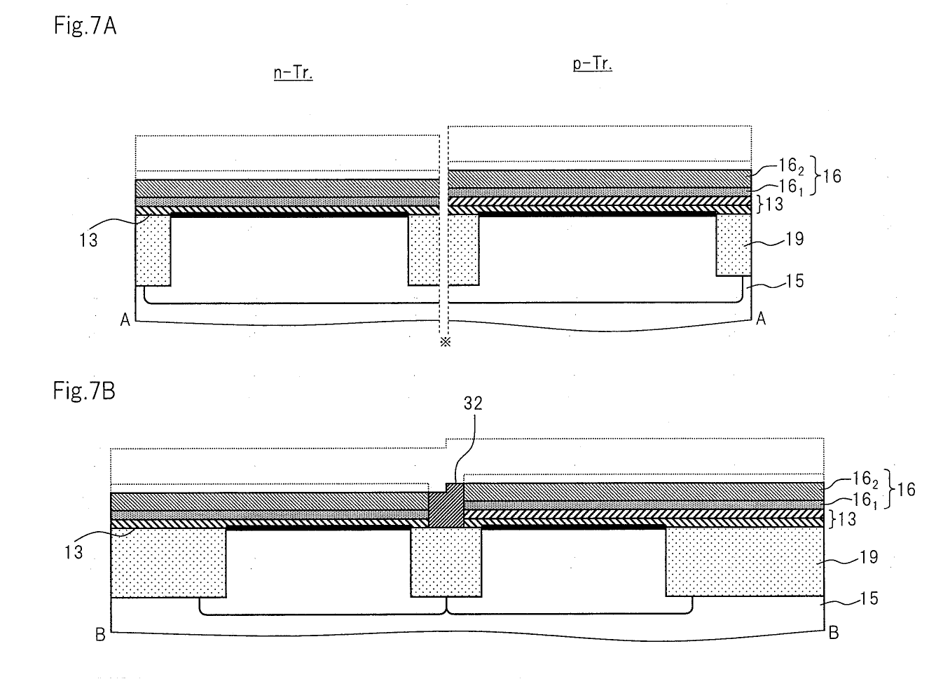

Then, as illustrated in FIGS. 7A and 7B, polycrystal silicon layer 34 on gate electrode 16 is removed by, for example, etching-back, and further protective layer 33 is removed by wet etching or the like. In this case, the polycrystal silicon layer remaining on the principal surface of semiconductor substrate 15 between the gate stacks becomes gate compensation film 32.

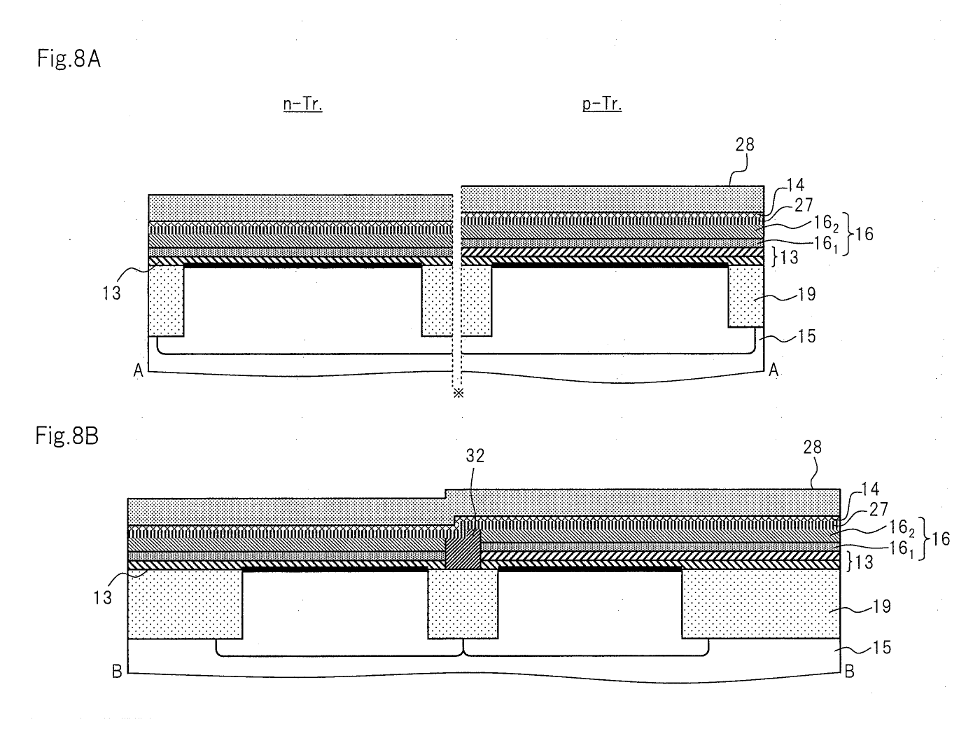

Next, as illustrated in FIGS. 8A and 8B, metal silicide film (e.g., WSi) 27 is formed on gate electrode 16 and gate compensation film 32, gate wiring (e.,g., W/WN: tungsten (W) or laminate structure of tungsten (W) and tungsten nitride (WN)) 14 is formed thereon, and cap layer 28 made of SiN or the like is further formed thereon by using, for example, P-CVD (plasma CVD).

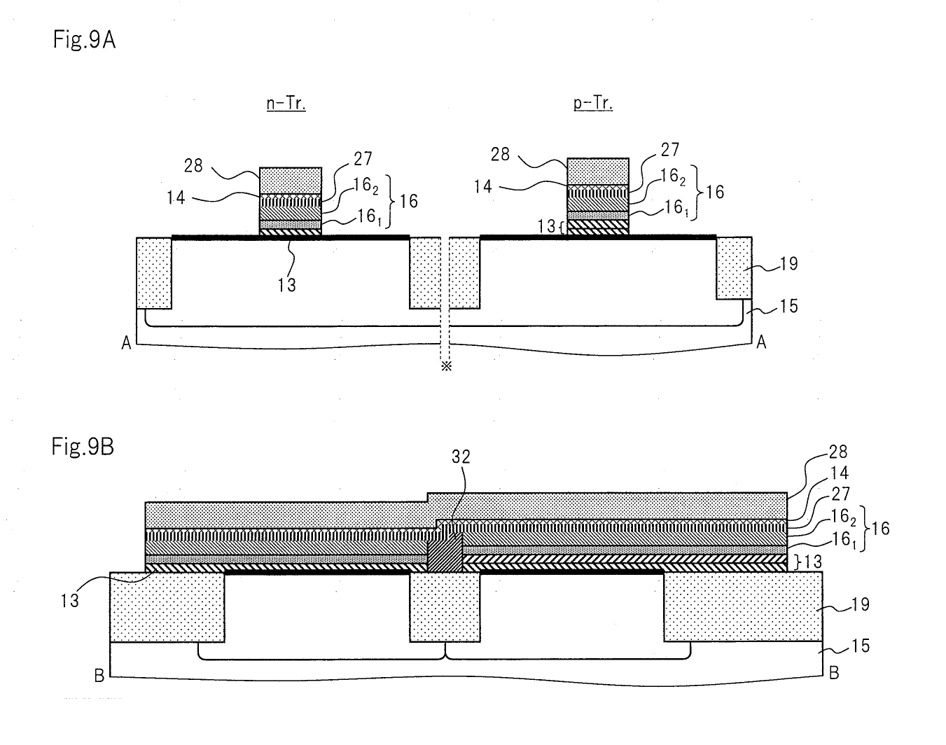

Then, as illustrated in FIGS. 9A and 9B, a gate stack including gate insulating film 13, gate electrode 16, metal silicide film 27, gate wiring 14, and cap layer 28 is patterned into a desired shape by using, for example, photolithography.

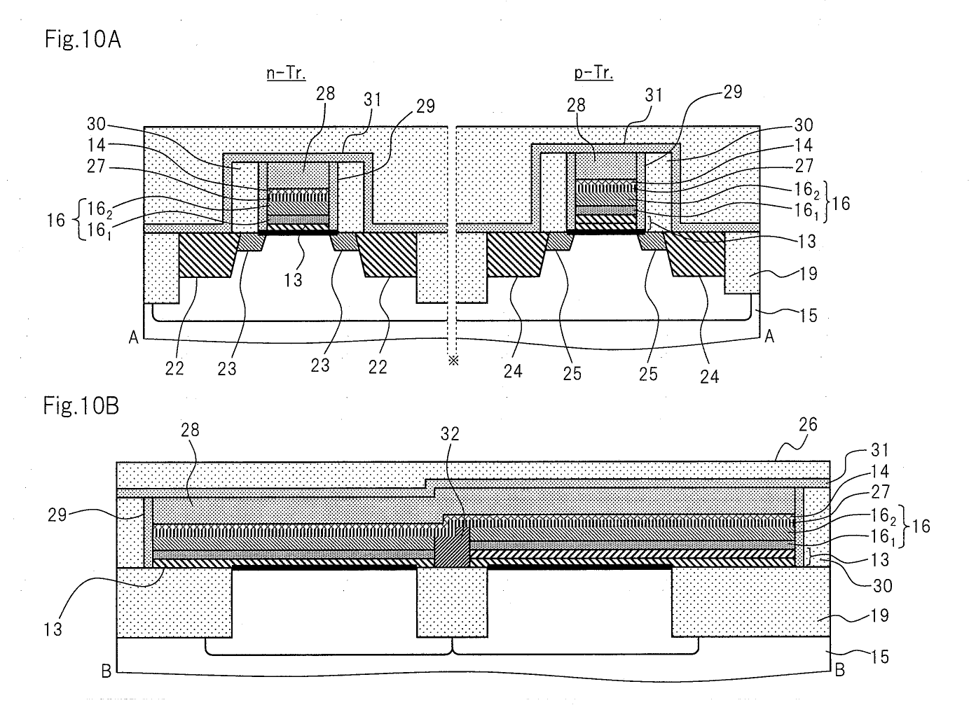

Then, as illustrated in FIGS. 10A and 10B, by using, for example, ion implantation, required impurity ions are diffused in semiconductor substrate 15 by using offset spacer (e.g., SiN) 29 and side wall spacer (e.g., SiO₂) 30 formed on the side face of the gate stack as masks, high density n-type impurity diffusion layer 22 and low density p-type impurity diffusion layer 23 serving as drains or sources are formed in the element forming region of n-type transistor 11, and high density p-type impurity diffusion layer 24 and low density n-type impurity diffusion layer 25 serving as drains or sources are formed in the element forming region of p-type transistor 12.

Then, to cover offset spacer 29 and side wall spacer 30, liner film 31 made of, for example, SiN, is formed. Then, interlayer insulating film 26 made of, for example, SOD (spin on dielectric), is formed on the entire surface of the semiconductor substrate, and the upper surface of interlayer insulating film 26 is planarized by etching-back or CMP (chemical mechanical polishing).

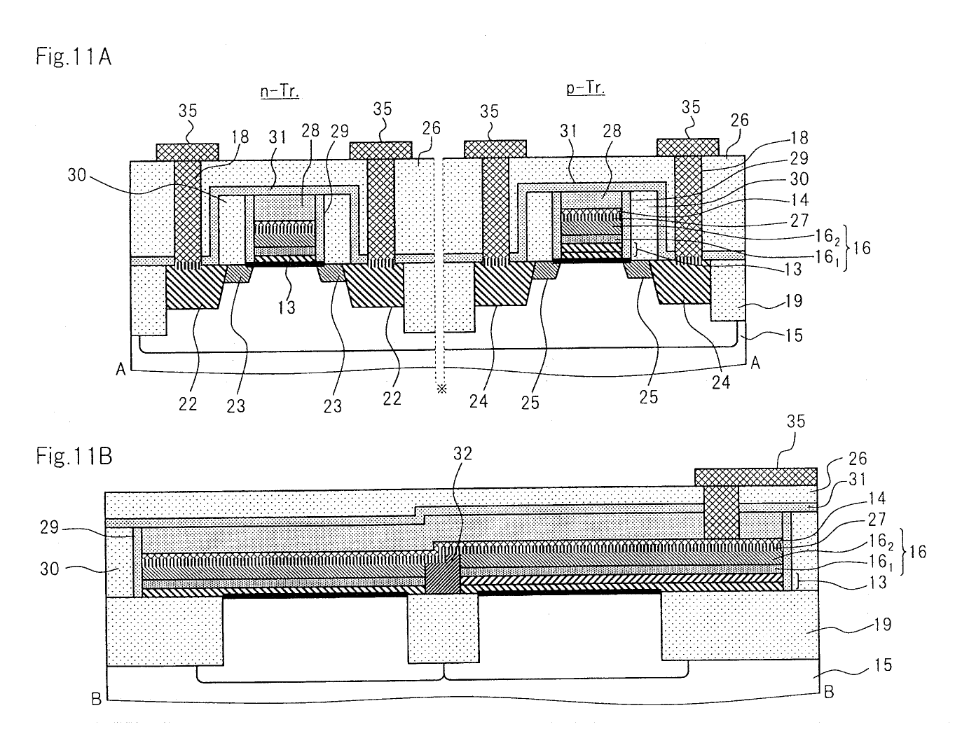

Lastly, as illustrated in FIGS. 11A and 11B, an opening is formed on interlayer insulating film 26 on the source or the drain of each of n-type transistor 11 and p-type transistor 12, a conductor film (e.g., W) is formed on the entire surface of interlayer insulating film 26 including the opening, and the conductor film is patterned into a required shape to form external wiring 35 connected to the source or the drain via contact 18.

### Second Embodiment

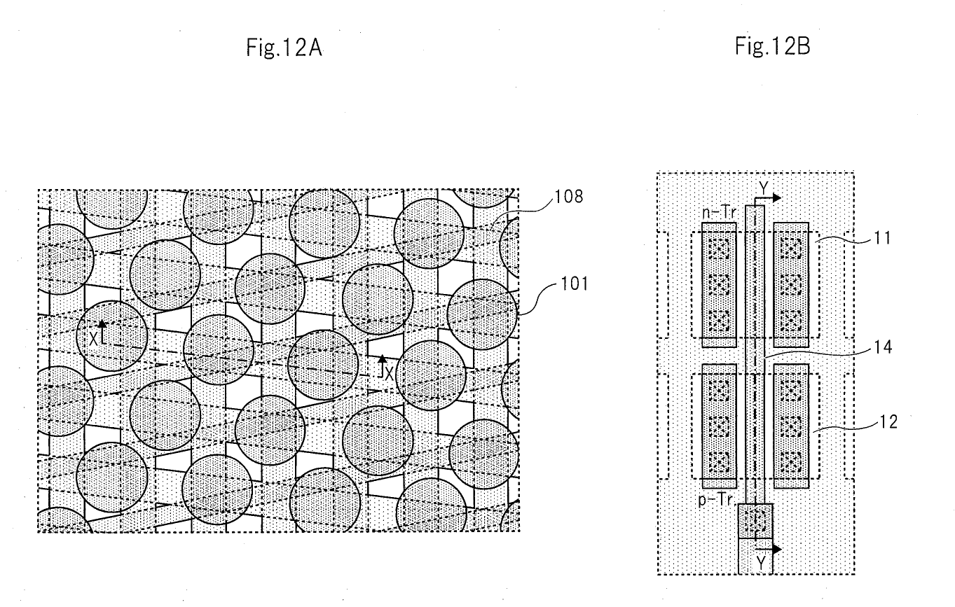

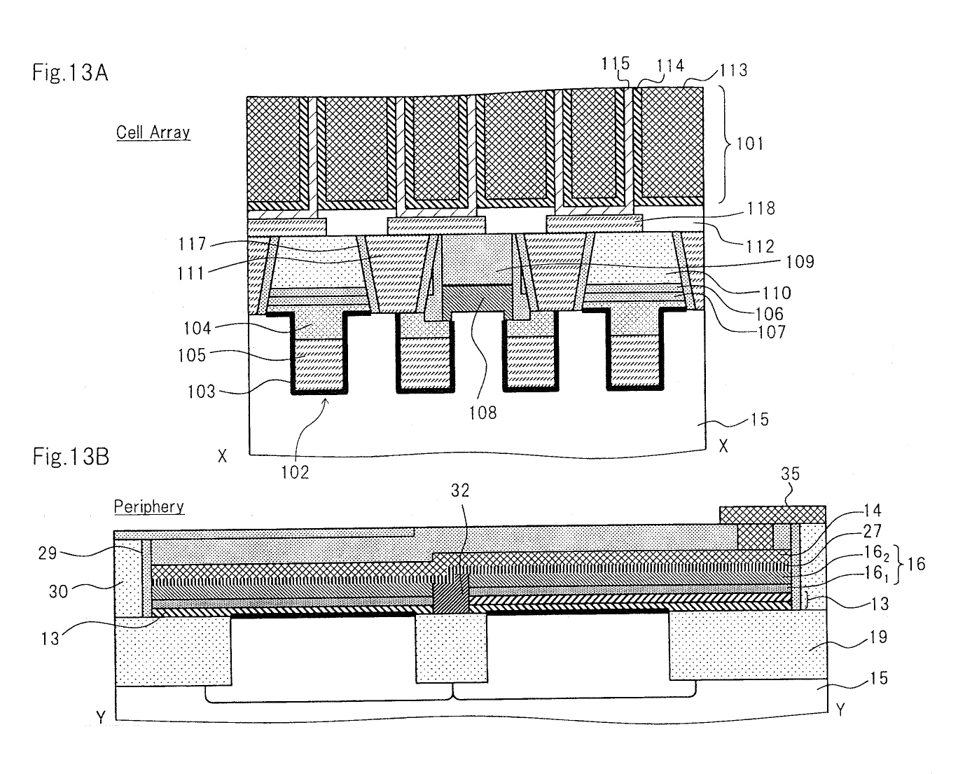

FIG. 12A is a plan view of a memory cell array region, illustrating a configuration example of a semiconductor device according to a second embodiment, and FIG. 12B is a plan view of a peripheral circuit region, illustrating the configuration example of the semiconductor device according to the second embodiment. FIG. 13A is a sectional view cut along line X-X of the memory cell array region illustrated in FIG. 12A, and FIG. 13B is a sectional view cut along line Y-Y of the peripheral circuit region illustrated in FIG. 12B.

FIG. 12A illustrates an example of the memory cell array region for storing information, which is included in a DRAM (dynamic random access memory), and FIG. 12B illustrates an example of the peripheral circuit region included in the DRAM. The peripheral circuit region includes, as in the case of the first embodiment, n-type transistor 11 and p-type transistor 12, and gate electrodes 16 of n-type transistor 11 and p-type transistor 12 are connected to each other by gate wiring 14.

The semiconductor device according to the second embodiment is an example where the present invention is applied to the DRAM, and a bit line for the memory cell array and gate wiring for each transistor for the peripheral circuit are simultaneously formed. In other words, the bit line for the memory cell array and the gate wiring for each transistor for the peripheral circuit have a similar configuration.

Generally, to improve refreshment characteristics of the DRAM, it is desirable to increase the capacity of a capacitor for storing information while reducing the capacity of the bit line. To reduce the capacity of the bit line, it is effective to use low-resistance material and reduce the film thickness. However, when the gate wiring of the transistor for the peripheral circuit is formed simultaneously with the bit line, the gate wiring of the transistor for the peripheral circuit is formed thin following thin-formation of the bit line. Accordingly, a possibility of disconnection of the gate wiring at a step between the gate stacks is greater. Thus, in this embodiment, the same configuration as that of the first embodiment is employed for the gate wiring of the transistor for the peripheral circuit.

As illustrated in FIG. 13A, the memory cell array includes a plurality of memory cells. The memory cell includes capacitor 101 for storing charges to store information, and cell transistor 102 for storing charges in capacitor 101 or discharging charges from capacitor 101.

The gage electrode (word line) of each cell transistor 102 includes a known buried word line (bWL) having, for example, a conductor buried in a trench formed in semiconductor substrate 15. In the inner wall of the trench, an oxide film or the like serving as gate insulating film 103 of cell transistor 102 is formed, and a conductor serving as gate electrode (word line) 105 is buried therein. The trench upper part including word line 105 is covered with bit contact interlayer insulating film 104 including an insulator (e.,g. SiN).

In the memory cell array region, bit line 108 including a conductor film is formed in an opening formed in bit contact interlayer insulating film 104, and hard mask layer 109 including an insulator is formed on bit line 108. The upper surface of bit contact interlayer insulating film 104 and the side faces of bit line 108 and hard mask layer 109 are covered with insulating film (e.g., SiN) 107, and liner film (e.g., SiN) 106 and interlayer insulating film (e.g., SOD film) 110 are deposited on insulating film 107. Further, on interlayer insulating film 110, silicon nitride layer 112 is deposited, and a structure (capacitor structure) serving as capacitor 101 is formed on silicon nitride layer 112. Capacitor 101 includes upper electrode 113, capacitance insulating film 114, and lower electrode 115. Lower electrode 115 of capacitor 101 and cell transistor 102 are connected to each other via capacity contact 111 formed in interlayer insulating film 110 and capacity contact pad 118 formed on interlayer insulating film 110. In the side wall of capacity contact 111, side wall film 117 including an insulating film can be formed.

In this embodiment, the memory cell is formed into a known stack structure where capacitor 101 is stacked on cell transistor 102, and word line 105 is formed into the bWL structure. However, each memory cell only needs to be configured such that each bit line 108 and gate wiring 14 of the transistor for the peripheral circuit are simultaneously formed, not limited to the configuration illustrated in FIG. 13A.

The transistor configuration for the peripheral circuit illustrated in FIG. 13B is similar to that of the first embodiment illustrated in FIGS. 4A to 4C, and thus description thereof will be omitted.

As illustrated in FIG. 13B, in the peripheral circuit, gate compensation film 32 is buried between n-type transistor 11 and p-type transistor 12 separately arranged on the principal surface of semiconductor substrate 15, and gate wiring 14 is formed on the upper surfaces of gate electrodes 16 of n-type transistor 11 and p-type transistor 12 and the upper surface of gate compensation film 32.

Specifically, the semiconductor device according to this embodiment includes, in the first region (peripheral circuit region) of the principal surface of semiconductor substrate 15, a first electrode (gate electrode 16) formed via a first insulating film (gate insulating film 13), a second electrode (gate electrode 16) formed via a second insulating film (gate insulating film 13), a compensation film (gate compensation film 32) buried between the first electrode and the second electrode, and first wiring (gate wiring 14) formed from the upper surface of the first electrode in contact with the upper surface of the first electrode and the upper surface of the second electrode through the upper surface of the compensation film to the upper surface of the second electrode, and in the second region (memory cell array region) of the principal surface of semiconductor substrate 15, a memory cell array including a plurality of memory cells for storing information, and second wiring (bit line) for interconnecting the plurality of memory cells. The first wiring and the second wiring are similar in configuration.

In this configuration, as in the case of the first embodiment, a step between the upper surfaces of gate electrodes 16 of n-type transistor 11 and p-type transistor 12 formed in the individual manufacturing processes to be separately arranged and the principal surface of semiconductor substrate 15 exposed between gate electrodes 16 is reduced by gate compensation film 32. Thus, wiring coverage of gate wiring 14 for interconnecting gate electrodes 16 of the transistors is improved, and disconnection of gate wiring 14 is prevented. Especially, when gate wiring 14 of the transistor for the peripheral circuit is thin because it is formed simultaneous with the bit line of the memory cell array, disconnection at the step part between the gate stacks is prevented.

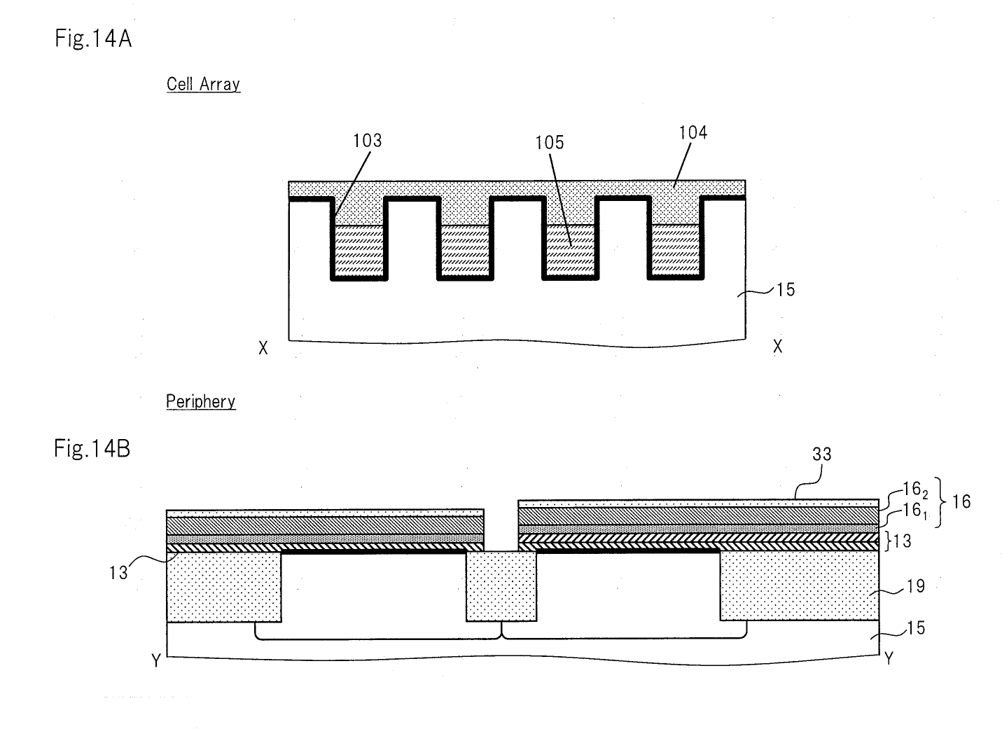

Next, referring to FIGS. 14A to 18B, a method for manufacturing the semiconductor device according to this embodiment will be described.

FIGS. 14A to 18B are sectional views illustrating an example of a manufacturing procedure of the semiconductor device according to the second embodiment: each A in FIGS. 14A to 18B is a sectional view cut along the line X-X of the memory cell array region illustrated in FIG. 12A, and each B in FIGS. 14A to 18B is a sectional view cut along the line Y-Y of the semiconductor device illustrated in FIG. 12B. However, each of FIGS. 14A to 18B illustrates a relationship between layers in the manufacturing process, and thus the plan views of FIGS. 12A and 12B do not correspond to all the sectional views of FIGS. 14A to 18B.

As illustrated in FIG. 14A, in the memory cell array region on semiconductor substrate 15, a plurality of word lines 105 of the bWL structure is formed. On the memory cell array region including word lines 105 and a trench upper part, bit contact interlayer insulating film 104 including, for example, a silicon nitride film, is formed. The bWL structure can be formed by using a known manufacturing method.

As illustrated in FIG. 14B, in the element forming regions of n-type transistor 11 and p-type transistor 12 of the peripheral circuit region, gas insulating films 13 made of high dielectric constant materials (e.g., HfO₂), are formed by using, for example, ALD. Metal film 16₁ made of TiN or the like is formed on each gate insulating film 13 by using, for example, PVD, and Si film 16₂ made of amorphous silicon or the like is further stacked thereon by using, for example, CVD, thereby forming gate electrode 16. FIG. 14B illustrates a configuration example where as gate insulating film 13 of p-type transistor 12, a film made of a high dielectric constant material (e.g., Al₂O₃) is further stacked on the HfO₂ film by using the ALD or the like. Any method can be used for changing the thickness of gate insulating film 13 at n-type transistor 11 or of p-type transistor 12. FIGS. 14A and 14B illustrate the example where the materials or film thicknesses of gate insulating film 13 of n-type transistor 11 is different from the materials or film thicknesses of gate insulating film 13 of p-type transistor 12. However, the materials or the film thicknesses of gate electrodes 16 can be different. FIG. 14A illustrates an example where protective layer 33 is further formed on Si film 16₂.

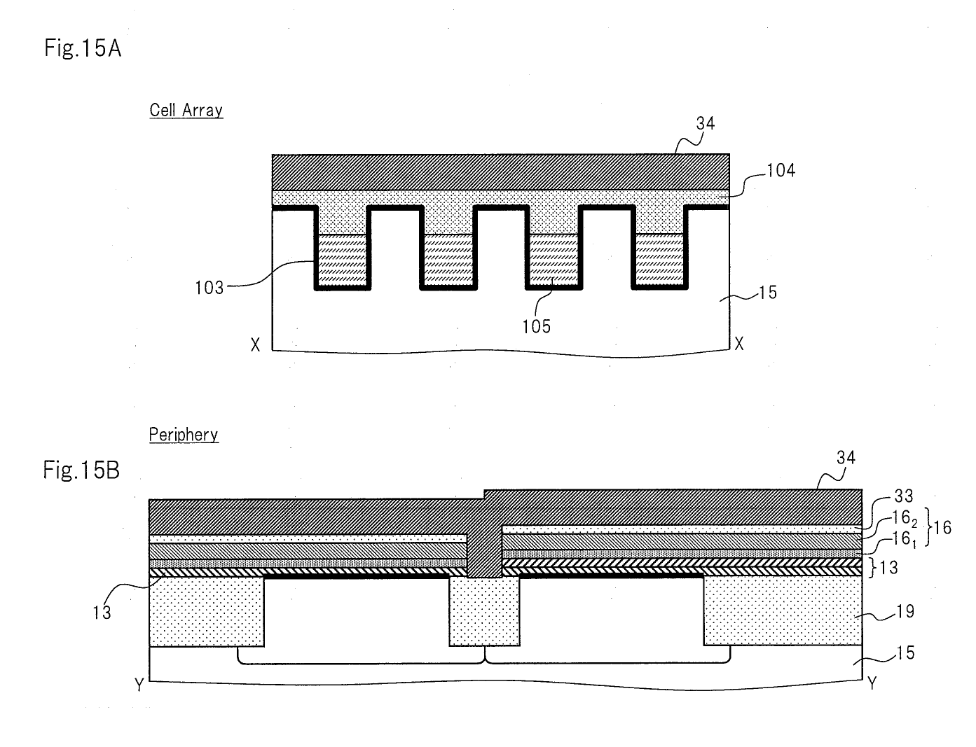

Then, as illustrated in FIGS. 15A and 15B, for example, polycrystal silicon (poly-Si) layer 34 is formed to cover gate electrodes 16 of the transistors of the memory cell array region and the peripheral circuit region.

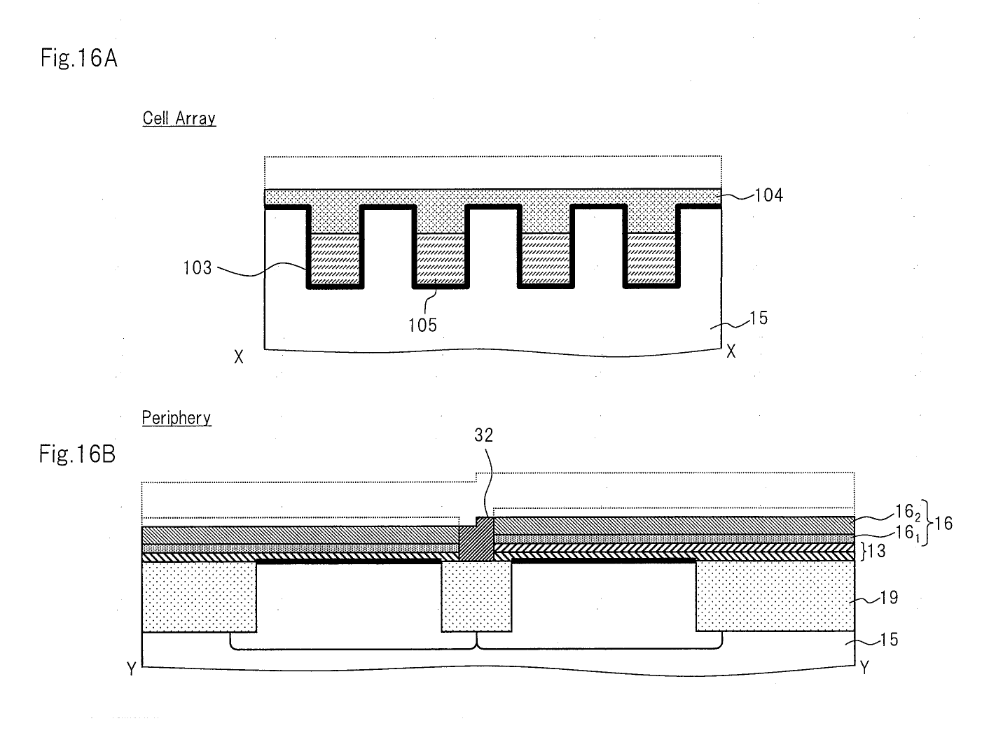

Then, as illustrated in FIGS. 16A and 16B, polycrystal silicon layer 34 on gate electrodes 16 of the memory cell array region and the peripheral circuit region are removed by, for example, etching-back, and further protective layer 33 is removed by wet etching or the like. In this case, the polycrystal silicon layer remaining on the principal surface of semiconductor substrate 15 between the gate stacks of the peripheral circuit region is gate compensation film 32 between the gates.

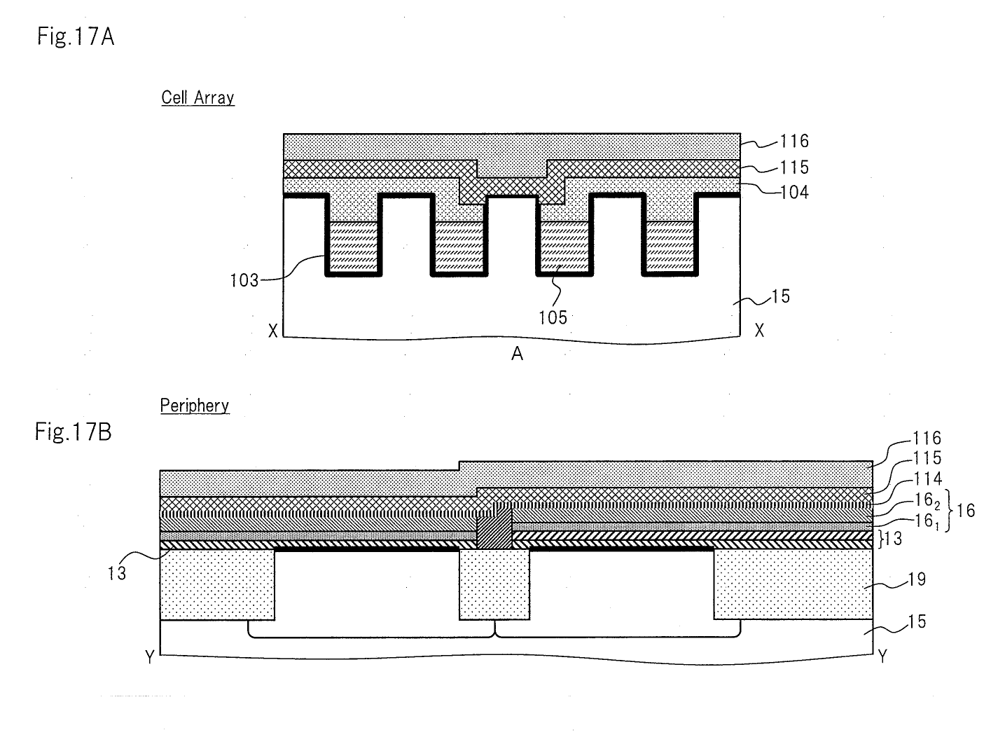

Then, as illustrated in FIG. 17A, by using, for example, photolithography, bit contact interlayer insulating film 104 of the required portion of the memory cell array region is removed to expose the semiconductor layer (principal surface of semiconductor substrate 15) serving as the source (or drain) of cell transistor 102. As illustrated in FIG. 17B, for example, metal silicide film (e.g., WSi) 114 is formed to cover gate electrode 16 of each transistor in the peripheral circuit region. Then, in the entire surface of the memory cell array region and the peripheral circuit region, conductor film (e.g., W/WN: tungsten (W) or laminate structure of tungsten (W) and tungsten nitride (WN)) 115 serving as bit line 108 of the memory cell array and gate wiring 14 of the peripheral circuit region is formed. Insulating layer (e.g., SiN) 116 serving as hard mask layer 109 of the memory cell array and a cap layer 28 of the peripheral circuit region is further formed thereon by using, for example, P-CVD. In the region from which bit contact interlayer insulating film 104 of the memory cell array region has been removed, as in the case of the peripheral circuit region, metal silicide film 114 can be formed, and then conductor film 115 and insulating layer 116 can be formed thereon.

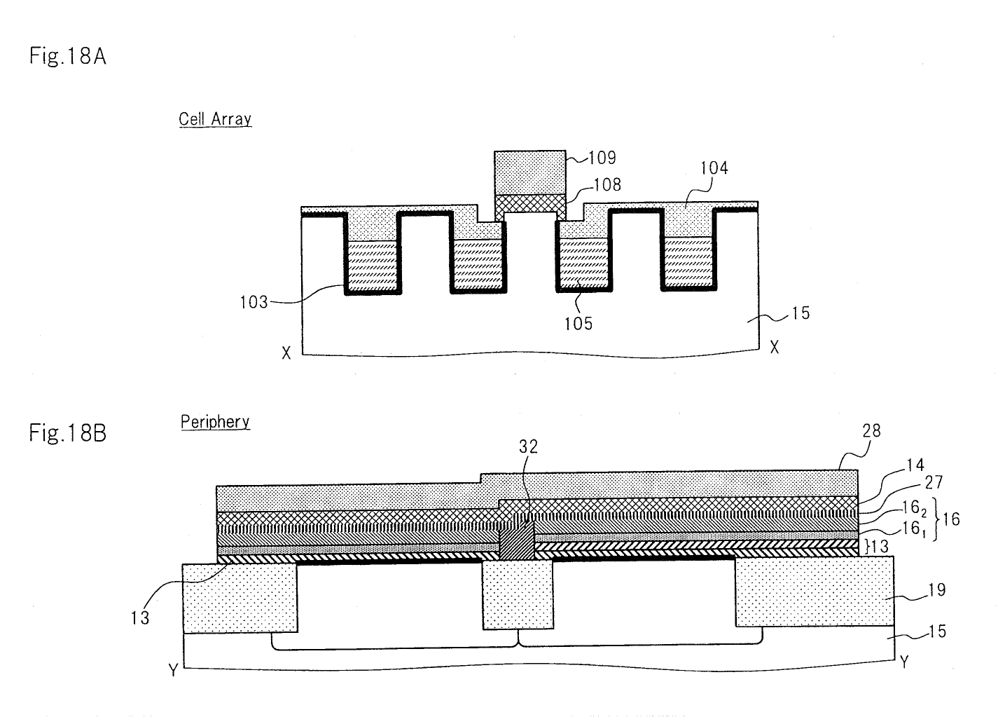

Then, as illustrated in FIG. 18A, conductor film 115 and insulating layer 116 in the memory array region are patterned into desired shapes by using, for example, photolithography, thereby forming bit line 108 and hard mask layer 109.

Though not illustrated in FIG. 18B, in this case, in the peripheral circuit region, for example, by using photolithography, metal silicide film 114, conductor film 115, and insulating layer 116 are patterned into desired shapes, and gate insulating film 13 and gate electrode 16 located below are patterned, thereby forming a gate stack (refer to FIG. 9A).

Then, in the memory cell array region, the side faces of bit contact interlayer insulating film 104, bit line 108 and hard mask layer 109 are covered with insulating film 107 made of, for example, silicon nitride, and liner film 106 and interlayer insulating film 110 are deposited on insulating film 107. Further, on interlayer insulating film 110, silicon nitride layer 112 is deposited, and capacitor 101 is formed on silicon nitride layer 112 (refer to FIG. 13A). Capacitor 101 can be formed by a known method, and detailed description thereof will be omitted.

On the other hand, in the peripheral circuit region, required impurity ions are diffused in semiconductor substrate 15 to form the sources or the drains of n-type transistor 11 and p-type transistor 12, interlayer insulating film 26 is deposited to cover cap layer 28 and the sources or the drains, and then external wiring 35 is formed on interlayer insulating film 26. Lastly, contact 18 is formed on interlayer insulating film 26 to interconnect the sources or the drains and external wiring 35 (refer to FIGS. 10A and 10B and FIGS. 11A and 11B).

Although the inventions has been described above in connection with several preferred embodiments thereof, it will be appreciated by those skilled in the art that those embodiments are provided solely for illustrating the invention, and should not be relied upon to construe the appended claims in a limiting sense.

What is claimed is:

1. A semiconductor device comprising:
a first electrode formed on a principal surface of a semiconductor substrate via a first insulating film;
a second electrode formed on the principal surface of said semiconductor substrate via a second insulating film;
a compensation film buried between said first electrode and said second electrode on the principal surface of said semiconductor substrate; and
a wiring formed from an upper surface of said first electrode through an upper surface of said compensation film to an upper surface of said second electrode to make contact with the upper surface of said first electrode and the upper surface of said second electrode,
wherein a height of said compensation film is not higher than one or more electrodes from among said first electrode and said second electrode.

2. The semiconductor device according to claim 1, wherein:
said first electrode is a gate electrode of a first transistor;
said second electrode is a gate electrode of a second transistor; and
said first transistor and said second transistor are field effect transistors of conductive types having reverse polarity.

3. The semiconductor device according to claim 1, wherein said compensation film is a conductor.

4. The semiconductor device according to claim 3, wherein said compensation film is film containing silicon.

5. The semiconductor device according to claim 1, wherein materials of said first insulating film and said second insulating film are different from each other.

6. The semiconductor device according to claim 1, wherein thicknesses of said first insulating film and said second insulating film are different from each other.

7. The semiconductor device according to claim 1, wherein materials of said first electrode and said second electrode are different from each other.

8. The semiconductor device according to claim 1, wherein thicknesses of said first electrode and said second electrode are different from each other.

9. The semiconductor device according to claim 1, wherein said first insulating film and said second insulating film are high-k insulating films made of insulators having higher dielectric constant than silicon dioxide.

10. The semiconductor device according to claim 1, wherein said first electrode and said second electrode are gate electrodes of transistors, namely, metal gates using metal materials for the gate electrodes.

11. The semiconductor device according to claim 1, wherein said first electrode and said second electrode are laminate films where films containing silicon are stacked on films made of metal materials.

12. The semiconductor device according to claim 1, wherein said wiring includes a metal silicide film.

13. The semiconductor device according to claim 1, wherein said wiring includes a laminate structure of tungsten or tungsten and tungsten nitride.

14. The semiconductor device according to claim 1, further comprising a memory cell array including a plurality of memory cells for storing information,
wherein a bit line for connecting said plurality of memory cells is similar in configuration to said wiring.

15. A semiconductor device comprising:
a first electrode formed on a principal surface of a semiconductor substrate via a first insulating film;
a second electrode formed on the principal surface of said semiconductor substrate via a second insulating film;
a first wiring formed to cover an upper surface of said first electrode in contact with said first electrode;
a second wiring formed to cover an upper surface of said second electrode in contact with said second electrode; and
a compensation film buried between side walls of said first electrode and said second electrode to make connect said first electrode and said second electrode to each other,
wherein said compensation film covers none of the upper surfaces of said first electrode and said second electrode; and
said first wiring and said second wiring are connected to each other on said compensation film located between said first electrode and said second electrode.

16. The semiconductor device according to claim 15, wherein said first insulating film and said second insulating film are high-k insulating films made of insulators having higher dielectric constant than silicon dioxide.

17. A semiconductor device comprising:
in a first region of a principal surface of a semiconductor substrate,
a first electrode formed via a first insulating film;
a second electrode via a second insulating film;
a compensation film buried between said first electrode and said second electrode; and
a first wiring formed from an upper surface of said first electrode through an upper surface of said compensation film to an upper surface of said second electrode to make contact with the upper surface of said first electrode and the upper surface of said second electrode; and
in a second region of the principal surface of said semiconductor substrate,
a memory cell array including a plurality of memory cells for storing information; and
a second wiring for connecting said plurality of memory cells to each other,
wherein said first wiring and said second wiring have same stacked layers.

18. The semiconductor device according to claim 17, wherein said first insulating film and said second insulating film are high-k insulating films made of insulators having higher dielectric constant than silicon dioxide.

19. The semiconductor device according to claim 17, wherein said first wiring and said second wiring include metal silicide films.

20. The semiconductor device according to claim 17, wherein said first wiring and said second wiring include a laminate structure of tungsten or tungsten and tungsten nitride.
